(19) United States
(12) Patent Application Publication
(10) Pub. No.: US 2024/0379376 A1
(43) Pub. Date: Nov. 14, 2024

(54) IMPLANT INTO EUV METAL OXIDE PHOTORESIST MODULE TO REDUCE EUV DOSE

(71) Applicant: Applied Materials, Inc., Santa Clara, CA (US)

(72) Inventors: Rajesh Prasad, Lexington, MA (US); Yung-Chen Lin, Westwood, MA (US); Zhiyu Huang, Sunnyvale, CA (US); Fenglin Wang, Lexington, MA (US); Chi-I Lang, Cupertino, CA (US); Hoyung David Hwang, Cupertino, CA (US); Edwin A. Arevalo, Beverly, MA (US); KyuHa Shim, Andover, MA (US)

(73) Assignee: Applied Materials, Inc., Santa Clara, CA (US)

(21) Appl. No.: 18/314,481

(22) Filed: May 9, 2023

(51) Int. Cl. H01L 21/3115; C23C 14/48; G03F 7/004; G03F 7/09; G03F 7/11

(52) U.S. Cl. CPC H01L 21/31155; C23C 14/48; G03F 7/0043; G03F 7/091; G03F 7/11

(57) ABSTRACT

Disclosed herein are approaches for reducing EUV dose during formation of a patterned metal oxide photoresist. In one approach, a method may include providing a stack of layers atop a substrate, the stack of layers comprising a film layer, and implanting the film layer with ions. The method may further include depositing a metal oxide photoresist atop the film layer, and patterning the metal oxide photoresist.

### FIELD OF THE DISCLOSURE

The present disclosure relates to semiconductor structures and, more particularly, to approaches for reducing extreme ultraviolet (EUV) dose during formation of a metal oxide photoresist.

### BACKGROUND OF THE DISCLOSURE

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. Multilevel interconnects require precise imaging and placement of high aspect ratio features. Reliable formation of these interconnects is needed to further increase device and interconnect density.

One process used to form various interconnect and other semiconductor features uses extreme ultraviolet (EUV) lithography. Conventional EUV patterning uses a multilayer stack in which a photoresist is patterned on top of a hardmask. Common hardmask materials are spin-on silicon anti-reflective coating (SiARC) and a deposited silicon oxynitride (SiON). The SiARC incorporates organic content to a silicon backbone, maintaining sufficient etch selectivity to the photoresist and underlying stack. Scaling the thickness of the SiARC backbone can be challenging and spin coating limits the minimum thickness that can be achieved without too many defects.

Several metal oxide materials have been tested as EUV hardmasks. The metal oxide films, including films with high EUV absorption elements were stoichiometric and not conductive. Furthermore, EUV lithography process generally takes a significant amount of exposure time and requires large amounts of energy.

Therefore, there is a need in the art for a multilayer stack and photoresist that allow for decreased dose time and/or lower dose energies.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a stack of layers atop a substrate, the stack of layers comprising a film layer, and implanting the film layer with ions. The method may further include depositing a metal oxide photoresist atop the film layer, and patterning the metal oxide photoresist.

In another aspect, a method of forming a semiconductor device may include providing a stack of layers atop a substrate, the stack of layers comprising a dielectric film layer, and implanting the dielectric film layer with ions. The method may further include depositing a metal oxide photoresist atop the dielectric film layer, and exposing and patterning the metal oxide photoresist.

In yet another aspect, a method of patterning a semiconductor device may include providing a stack of layers atop a substrate, the stack of layers comprising a dielectric film layer, and implanting the dielectric film layer with ions. The method may further include depositing a metal oxide photoresist atop the dielectric film layer, and exposing and patterning the metal oxide photoresist.

In still yet another aspect, a non-transitory computer readable storage medium is provided. The non-transitory computer readable storage medium includes a plurality of instructions, the plurality of instructions including instructions to control components of a processing system to perform the process of patterning a semiconductor device may include providing a stack of layers atop a substrate, the stack of layers comprising a dielectric film layer, and implanting the dielectric film layer with ions. The plurality of instructions may further include instructions to control components of the processing system to perform the process of depositing a metal oxide photoresist atop the dielectric film layer, and exposing and patterning the metal oxide photoresist.

In still yet another aspect, a system may include a processor and a memory storing instructions executable by the processor to implant a dielectric film layer with ions, wherein the dielectric film is part of a stack of layers formed atop a substrate, and wherein the dielectric film layer is implanted with ions before a metal oxide photoresist is deposited atop the dielectric film layer and before the metal oxide photoresist is exposed and patterned.

### BRIEF DESCRIPTION OF THE DRAWINGS

The accompanying drawings illustrate exemplary approaches of the disclosure, including the practical application of the principles thereof, as follows:

FIG. 1 illustrates a side cross-sectional view of a device, including a stack of layers over a substrate, according to embodiments of the present disclosure;

FIG. 2 illustrates a side cross-sectional view of the device during an ion implant, according to embodiments of the present disclosure;

FIG. 3 illustrates a side cross-sectional view of the device following formation of a patterned photoresist, according to embodiments of the present disclosure;

FIG. 4 illustrates a diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Devices, semiconductor structures, and methods in accordance with the present disclosure will now be described more fully hereinafter with reference to the accompanying drawings, where various embodiments are shown. The devices, semiconductor structures, and methods may be embodied in many different forms and are not to be construed as being limited to the embodiments set forth herein. Instead, these embodiments are provided so the disclosure will be thorough and complete, and will fully convey the scope of the methods to those skilled in the art.

Cost of EUV lithography systems is extremely high. Subsequently, the throughput of such tools becomes a concern. Metal oxide photoresists that are sensitive to EUV photons allows for easier exposure of the photoresist. However, achieving a lower EUV dose (e.g., 15%-30% lower) is desired. Embodiments of the present disclosure include an ion implant to a dielectric layer beneath the metal oxide photoresist, which benefits the photoresist exposure by implanting certain elements into the metal oxide photoresist underlayer that enables the generation of secondary electrons to further expose the photoresist and meet the EUV dose reduction entitlement. In some embodiments, the ion implant includes iodine and/or indium, which has been shown to significantly reduce EUV lithography dose when used in conjunction with a metal oxide photoresist.

The embodiments herein accommodate different film stacks and can be used in a variety of patterning applications. Also, as compared with PVD and CVD film deposition, the ion implantation technique of the present disclosure enables high ion concentration and depth to be accurately controlled. With controlled ion concentration and peak concentration depth, certain elements can be adjusted from the surface, and Q-time issue can potentially be mitigated.

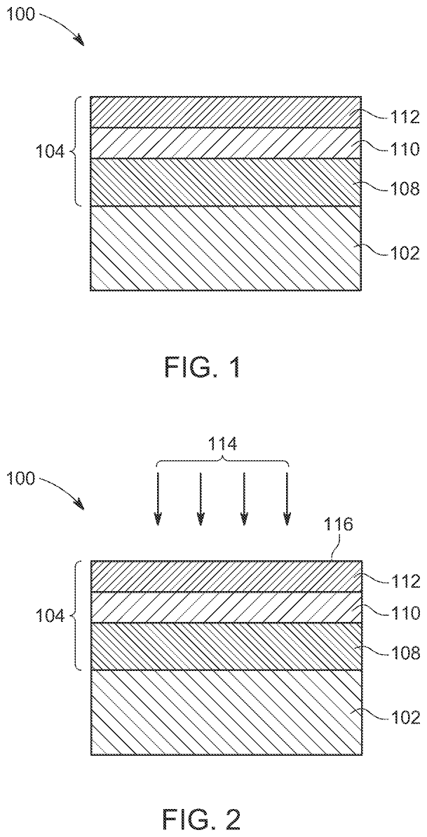

FIG. 1 illustrates a side cross-sectional view of a semiconductor device (hereinafter “device”) 100. As shown, the device 100 may include a substrate 102 and a stack of layers 104 formed over the substrate 102. In some embodiments, the stack of layers 104 may include a tetraethyl orthosilicate (TEOS) layer 108 formed atop the substrate 102, a spin-on carbon layer 110 formed atop the TEOS layer 108, and a film layer 112 formed over the spin-on carbon layer 110. In some embodiments, the film layer 112 is a dielectric film layer deposited or otherwise formed directly atop the spin-on carbon layer 110. Although non-limiting, in one embodiment, the TEOS layer 108 may be approximately 500A thick, the spin-on carbon layer 110 may be approximately 600A thick, and the film layer 112 may be approximately 150A thick. In other embodiments, the film layer 112 may be any of silicon carbide, silicon oxycarbide, carbon-based film, silicon, oxide, silicon oxynitride, or silicon nitride.

As shown in FIG. 2, an ion implant process may then be performed whereby ions 114 are directed into an upper surface 116 of the film layer 112. In some embodiments, the ions species may include indium or iodine. Although non-limiting, iodine may be delivered into the film layer 112 at an energy and dose of 1.8 keV, 5.8E15, while indium may be delivered into the film layer 112 at an energy and dose of 1.8 keV, 6.6E15. It will be appreciated that the energy and dose may vary, however, such as when the film layer 112 has a different thickness or is a different material, e.g., a low-density film. The implant energy may therefore range between 0.2 and 10 keV, and the implant dose may range between 1E14-1E16 in various embodiments. The temperature during implant of the ions 114 may be between approximately −100° C. and approximately 550° C. In still other embodiments, the ion species may be any of fluorine, xenon, antimony, manganese, gallium, selenium, or tin.

Advantageously, using a beamline ion implantation into the device 100 allows accurate control of the ions 114 to a desired depth within the stack 104. For example, if the film layer 112 is 150A thick, it maybe undesirable to have the ions 114 diffuse into the spin-on carbon layer 110 or the TEOS layer 108. As such, implant energy and/or dose may be selected to ensure diffusion only partially into/through the film layer 112. From a EUV dose perspective, it maybe optimum to place the ions near the middle or towards the top half of the film layer 112. To do this using a traditional film deposition technique would entail a dual deposition recipe, which negatively impacts overall throughput.

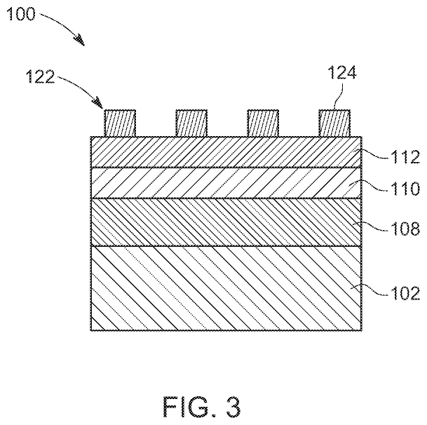

Next, as shown in FIG. 3, a metal oxide photoresist layer 122 may be formed atop the film layer 112 and then patterned to form a plurality of photoresist features 124. Although non-limiting, the metal oxide photoresist layer 122 may be formed by a PVD process, wherein the metal oxide photoresist layer 122 can be a metal rich oxide layer that provides ample secondary electrons when excited by EUV radiation. A metal rich oxide layer including a high-Z metal and lower resistance are considered for the EUV process to reduce the EUV dose energies. The high-Z metal refers to a metal having an atomic number greater than or equal to 40, and may include one or more of tin (Sn), indium (In), gallium (Ga), zinc (Zn), tellurium (Te), antimony (Sb), nickel (Ni), titanium (Ti), aluminum (Al), or tantalum (Ta). Examples of the metal rich oxide layer include tin oxide (SnOₓ), indium gallium zinc oxide (IGZO), indium tin oxide (ITO), tantalum oxide (TaOₓ), or other suitable metal rich oxide. The metal rich oxide layer is formed by the PVD process that can produce a metal oxide layer having nonstoichiometric ratio of metal to oxide, such as higher metal content. For example, a stoichiometric metal oxide layer can be characterized as MxOy, where M is one or more metals, and the stoichiometric metal to oxide ratio is x to y. A metal rich oxide layer produced by the PVD process can have a metal to oxide ratio of about 1.5 x-to-y or greater, such as about 2 x-to-y or greater.

During operation, the metal oxide photoresist layer 122 is patterned to form the photoresist features 124. The metal oxide photoresist layer 122 can be a positive resist that becomes soluble upon exposure to radiation, or a negative resist that becomes insoluble upon exposure to radiation. The radiation can have a wavelength in the EUV range. Advantageously, the previous ion implant into the film layer 112 allows the generation of secondary electrons via interaction with the EUV photons that further expose the metal oxide photoresist layer 122, thereby allowing for a lower EUV dose and greater throughput as a result. For example, implant recipes for iodine and indium may achieve between 15% and 25% EUV dose reduction in some non-limiting embodiments. Although not shown, the pattern defined by the photoresist features 124 may then be transferred to the film stack 104 by one or more etching processes to create lines and/or trenches, as desired.

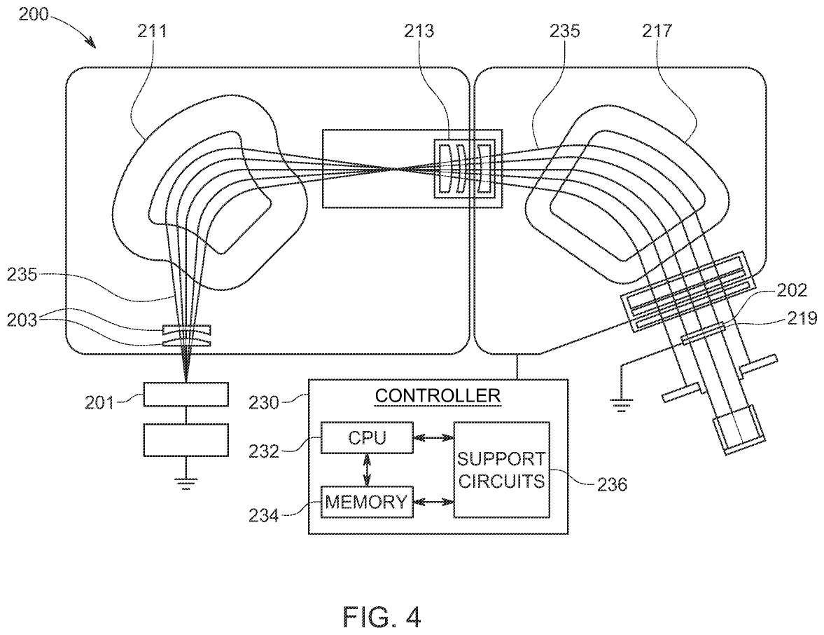

FIG. 4 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the ion implant demonstrated in FIG. 2.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. The substrate 202 may be the same as the substrate 102 described above. The substrate 202 may be moved in one or more dimensions (e.g., translate, rotate, tilt, etc.) by a platform component sometimes referred to as a “roplat” (not shown). It is also contemplated that the platen 219 may be configured to perform the heated implantation processes described herein to modify one or more waveguide surfaces.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

For example, the non-transitory computer readable storage medium may include a plurality of instructions, the plurality of instructions including instructions to control components of a processing system to perform the process of patterning a semiconductor device may include providing a stack of layers atop a substrate, the stack of layers comprising a dielectric film layer, and implanting the dielectric film layer with ions. The plurality of instructions may further include instructions to control components of the processing system to perform the process of depositing a metal oxide photoresist atop the dielectric film layer, and exposing and patterning the metal oxide photoresist.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a stack of layers atop a substrate, the stack of layers comprising a film layer;
implanting the film layer with ions;
depositing a metal oxide photoresist atop the film layer; and
patterning the metal oxide photoresist.

2. The method according to claim 1, wherein the film layer is a dielectric film.

3. The method of claim 1, wherein the film layer is a silicon anti-reflective coating.

4. The method of claim 1, wherein the film layer is one of: silicon carbide, silicon oxycarbide, carbon-based film, silicon, oxide, silicon oxynitride, or silicon nitride.

5. The method of claim 1, wherein providing the stack of layers atop the substrate comprises:
forming a tetraethyl orthosilicate layer atop the substrate;
forming a spin-on carbon layer atop the tetraethyl orthosilicate layer; and
forming the film layer over the spin-on carbon layer.

6. The method of claim 1, wherein patterning the metal oxide photoresist comprises exposing the metal oxide photoresist.

7. The method of claim 1, wherein implanting the film layer with ions comprises delivering iodine or indium into an upper surface of the film layer.

8. A method of forming a semiconductor device, comprising:
providing a stack of layers atop a substrate, the stack of layers comprising a dielectric film layer;
implanting the dielectric film layer with ions;
depositing a metal oxide photoresist atop the dielectric film layer; and
exposing and patterning the metal oxide photoresist.

9. The method of claim 8, wherein the dielectric film layer is a silicon anti-reflective coating.

10. The method of claim 8, wherein the dielectric film layer is one of: silicon carbide, silicon oxycarbide, carbon-based film, silicon, oxide, silicon oxynitride, or silicon nitride.

11. The method of claim 8, wherein providing the stack of layers atop the substrate comprises:
forming a tetraethyl orthosilicate layer atop the substrate;
forming a spin-on carbon layer atop the tetraethyl orthosilicate layer; and
forming the dielectric film layer over the spin-on carbon layer.

12. The method of claim 8, wherein implanting the film layer with ions comprises delivering iodine or indium into an upper surface of the dielectric film layer.

13. A system, comprising:
a processor; and
a memory storing instructions executable by the processor to implant a dielectric film layer with ions, wherein the dielectric film is part of a stack of layers formed atop a substrate, and wherein the dielectric film layer is implanted with ions before a metal oxide photoresist is deposited atop the dielectric film layer and before the metal oxide photoresist is exposed and patterned.

14. The system of claim 13, wherein the dielectric film layer is a silicon anti-reflective coating.

15. The system of claim 13, wherein the dielectric film layer is one of: silicon carbide, silicon oxycarbide, carbon-based film, silicon, oxide, silicon oxynitride, or silicon nitride.

16. The system of claim 13, wherein the instructions executable by the processor to provide the stack of layers atop the substrate further comprises:
forming a tetraethyl orthosilicate layer atop the substrate;
forming a spin-on carbon layer atop the tetraethyl orthosilicate layer; and
forming the dielectric film layer over the spin-on carbon layer.

17. The system of claim 16, wherein the instructions executable by the processor to implant the dielectric film layer with ions causes the ions to diffuse to a depth below the dielectric film layer.

18. The system of claim 13, wherein the instructions executable by the processor to implant the dielectric film layer with ions causes the ions to diffuse only partially within the dielectric film layer.

19. The system of claim 13, wherein the instructions executable by the processor to implant the film layer with ions comprises instructions to deliver iodine or indium into an upper surface of the dielectric film layer.

20. The system of claim 13, wherein the instructions executable by the processor to implant the film layer with ions comprises instructions to deliver at least one of the following ion species into an upper surface of the dielectric film layer: fluorine, xenon, antimony, manganese, gallium, selenium, and tin.
